(19) United States
(12) Patent Application Publication
(10) Pub. No.: US 2015/0287752 A1
(43) Pub. Date: Oct. 8, 2015

(54) SENSOR SUBSTRATE, METHOD OF MANUFACTURING THE SAME, AND DISPLAY APPARATUS HAVING THE SAME

(71) Applicant: Samsung Display Co., Ltd., Yongin-City (KR)

(72) Inventors: YUNJONG YEO, Seoul (KR); JI HUN KIM, Asan-si (KR); Hyunmin CHO, Asan-si (KR)

(21) Appl. No.: 14/599,695

(22) Filed: Jan. 19, 2015

(30) Foreign Application Priority Data
Apr. 8, 2014 (KR) 10-2014-0041912

(51) Int. Cl. H01L 27/144; H01L 31/032; H01L 21/465; H01L 29/786; H01L 29/66; H01L 31/0232; H01L 31/113; H01L 31/18

(52) U.S. Cl. CPC H01L 27/1443; H01L 31/1136; H01L 31/032; H01L 31/18; H01L 29/7869; H01L 29/66969; H01L 31/02327; H01L 21/465

(57) ABSTRACT

A sensor substrate includes a base substrate, and a sensing transistor and a switching transistor, which are on the base substrate. The sensing transistor includes a first gate electrode, an optical response pattern on the first gate electrode, a first source electrode and a first drain electrode on the optical response pattern and spaced apart from each other, a first oxide semiconductor pattern between the first source electrode and the optical response pattern, and a second oxide semiconductor pattern between the first drain electrode and the optical response pattern. The switching transistor includes a second gate electrode, a third oxide semiconductor pattern on the second gate electrode, and a second source electrode and a second drain electrode on the third oxide semiconductor pattern to be spaced apart from each other.

This application claims priority to Korean Patent Application No. 10-2014-0041912, filed on Apr. 8, 2014, and all the benefits accruing therefrom under 35 U.S.C. §119, the contents of which are hereby incorporated by reference.

### BACKGROUND

1. Field

The invention relates to a sensor substrate, a method of manufacturing the sensor substrate, and a display apparatus having the sensor substrate. More particularly, the invention relates to a sensor substrate having an optical detection function, a method of manufacturing the sensor substrate, and a display apparatus having the sensor substrate.

2. Description of the Related Art

A liquid crystal display is one display device among flat panel display devices that have been extensively used and includes two substrates each having an electrode formed thereon and a liquid crystal layer interposed between the two substrates. In the liquid crystal display, a signal is applied to the electrodes to realign liquid crystal molecules of the liquid crystal layer, and thus an amount of light passing through the liquid crystal layer is controlled.

### SUMMARY

A liquid crystal display having a touch detection function or an image detection function has been studied. In order to realize the touch detection function and the image detection function, the liquid crystal display includes an optical detection sensor including an infrared light detection thin film transistor, a visible light detection thin film transistor and a switching thin film transistor.

One or more exemplary embodiment of the invention provides a sensor substrate capable of simplifying a manufacturing process thereof and improving a yield thereof

One or more exemplary embodiment of the invention provides a method of manufacturing the sensor substrate.

One or more exemplary embodiment of the invention provides a display apparatus having the sensor substrate.

An exemplary embodiment of the invention provides a sensor substrate including a base substrate, a sensing transistor on the base substrate, and a switching transistor on the base substrate. The sensing transistor includes a first gate electrode, an optical response pattern on the first gate electrode, a first source electrode and a first drain electrode, which are on the optical response pattern and spaced apart from each other, a first oxide semiconductor pattern between the first source electrode and the optical response pattern, and a second oxide semiconductor pattern between the first drain electrode and the optical response pattern. The switching transistor includes a second gate electrode, a third oxide semiconductor pattern on the second gate electrode, and a second source electrode and a second drain electrode, which are on the third oxide semiconductor pattern and spaced apart from each other.

An exemplary embodiment of the invention provides a method of manufacturing the sensor substrate, including forming a first gate electrode and a second gate electrode on a base substrate, forming a gate insulating layer to cover the first and second gate electrodes, forming an optical response layer on the gate insulating layer, forming a first photosensitive pattern on the optical response layer, etching the optical response layer using the first photosensitive pattern as a mask to form an optical response pattern of a sensing transistor, forming an oxide semiconductor layer on the gate insulating layer and the optical response pattern, forming a metal layer on the oxide semiconductor layer, forming a second photosensitive pattern on the metal layer, first etching the oxide semiconductor layer and the metal layer using the second photosensitive pattern as a mask to form, a first source electrode and a first drain electrode on the first gate electrode, a first oxide semiconductor pattern between the first source electrode and the optical response pattern, a second oxide semiconductor pattern between the first drain electrode and the optical response pattern, of the sensing transistor, and to form, a metal pattern and a third oxide semiconductor pattern on the second gate electrode, of a switching transistor, etching back the second photosensitive pattern to form a third photosensitive pattern, and second etching the metal layer using the third photosensitive pattern as a mask to form a second source electrode and a second drain electrode, which are on the third oxide semiconductor pattern and spaced apart from each other, of the switching transistor.

An exemplary embodiment of the invention provides a display apparatus including a pixel substrate including a plurality of pixels which is disposed thereon and displays an image, and a sensor substrate facing and coupled to the pixel substrate and including a plurality of sensing transistors which is disposed thereon and senses a light.

The sensor substrate includes a base substrate, a sensing transistor among the plurality of the sensing transistors on the base substrate, and a switching transistor on the base substrate. The sensing transistor includes a first gate electrode, an optical response pattern on the first gate electrode, a first source electrode and a first drain electrode, which are on the optical response pattern and spaced apart from each other, a first oxide semiconductor pattern between the first source electrode and the optical response pattern, and a second oxide semiconductor pattern between the first drain electrode and the second oxide semiconductor pattern. The switching transistor includes a second gate electrode, a third oxide semiconductor pattern on the second gate electrode, and a second source electrode and a second drain electrode, which are on the third oxide semiconductor pattern and spaced apart from each other.

According to one or more exemplary embodiment of the invention, the optical response layer is patterned by the dry etching process to form the optical response pattern. Then, the oxide semiconductor pattern patterned by the wet etching process serves as the channel layer of the switching transistor. Thus, the manufacturing process of the sensor substrate may be simplified and the yield of the sensor substrate may be improved.

### BRIEF DESCRIPTION OF THE DRAWINGS

The above and other advantages of the disclosure will become readily apparent by reference to the following detailed description when considered in conjunction with the accompanying drawings wherein:

FIG. 1 is a cross-sectional view showing an exemplary embodiment of a sensor substrate according to the invention;

FIG. 2 is a cross-sectional view showing another exemplary embodiment of a sensor substrate according to the invention;

FIGS. 3A to 3H are cross-sectional views showing an exemplary embodiment of a manufacturing process of the sensor substrate shown in FIG. 1 according to the invention;

FIGS. 4A to 4G are cross-sectional views showing an exemplary embodiment of a manufacturing process of the sensor substrate shown in FIG. 2 according to the invention;

FIGS. 5A to 5D are cross-sectional views showing another exemplary embodiment of a manufacturing process of the sensor substrate shown in FIG. 2 according to the invention;

FIG. 6 is a block diagram showing an exemplary embodiment of a display apparatus according to the invention;

FIG. 7 is a circuit diagram showing an exemplary embodiment of a plurality of sensors of a display apparatus according to the invention;

FIG. 8 is a cross-sectional view showing an exemplary embodiment of a display panel of a display apparatus according to the invention;

FIG. 9 is a plan view showing an exemplary embodiment of a sensor substrate of a display panel according to the invention; and

FIG. 10 is an enlarged plan view showing an exemplary embodiment of a sensor of a sensor substrate according to the invention.

### DETAILED DESCRIPTION

The invention is described more fully hereinafter with reference to the accompanying drawings, in which exemplary embodiments of the invention are shown. This invention may, however, be embodied in many different forms and should not be construed as limited to the exemplary embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, connected may refer to elements being physically and/or electrically connected to each other. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the invention.

Spatially relative terms, such as “lower,” “under,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “under” other elements or features would then be oriented “above” the other elements or features. Thus, the exemplary term “under” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the disclosure. As used herein, the singular forms, “a,” “an” and “the” are intended to include the plural forms as well, unless the context clearly indicates otherwise. It will be further understood that the terms “includes” and/or “including,” when used in this specification, specify the presence of stated features, integers, steps, operations, elements, and/or components, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, the invention will be explained in detail with reference to the accompanying drawings.

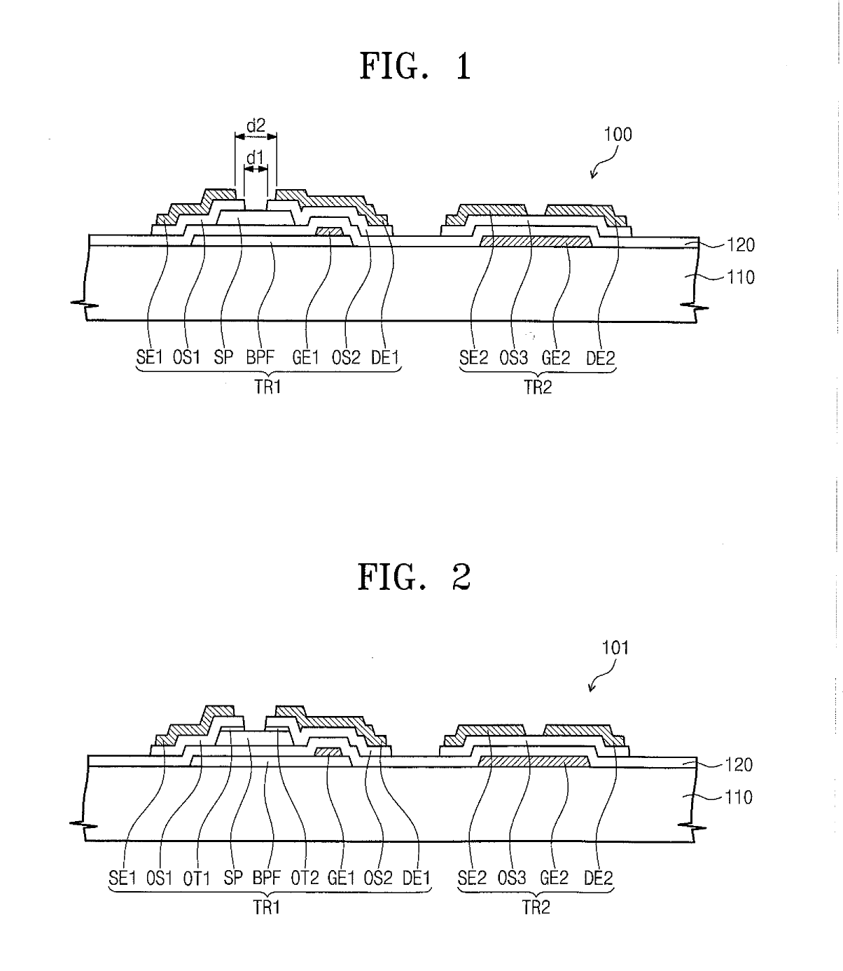

FIG. 1 is a cross-sectional view showing an exemplary embodiment of a sensor substrate 100 according to the invention.

Referring to FIG. 1, the sensor substrate 100 includes a base substrate 110, and a sensing transistor TR1 and a switching transistor TR2 which are disposed on the base substrate 110. The sensing transistor TR1 is electrically connected to the switching transistor TR2 to form a sensor, and the sensor may further include a capacitor (not shown) connected to the sensing transistor TR1 and the switching transistor TR2.

The base substrate 110 may be a transparent glass or plastic substrate. The sensing transistor TR1 may be configured to have a thin film transistor including an optical response pattern SP that is responsive to infrared light. As an exemplary embodiment, the optical response pattern SP may include amorphous germanium (a-Ge) or amorphous silicon germanium (a-SiGe).

In addition, the sensing transistor TR1 further includes a band-pass filter pattern BPF, a first gate electrode GE1, a first oxide semiconductor pattern OS1, a second oxide semiconductor pattern OS2, a first source electrode SE1 and a first drain electrode DE1.

The band-pass filter pattern BPF includes a material that blocks visible light among lights provided from outside the sensor substrate 100. The band-pass filter pattern BPF includes an organic material including a black pigment, amorphous silicon (a-Si), amorphous germanium (a-Ge) or amorphous silicon germanium (a-SiGe). The band-pass filter pattern BPF blocks the visible light incident to the sensor substrate 100 from the outside to improve a signal to noise ratio (“SNR”) and to optimize sensitivity of the optical response pattern SP which includes amorphous silicon germanium or amorphous germanium, against an infrared light region, thereby efficiently reducing or effectively preventing the sensor substrate from being affected by the visible light.

The first gate electrode GE1 is disposed on one side of an upper surface of the band-pass filter pattern BPF. That is, the first gate electrode GE1 is disposed on the one side of the band-pass filter pattern BPF such that the infrared light provided from the outside travels to the optical response pattern SP without being blocked by the first gate electrode GE1. The first gate electrode GE1 includes a single-layer structure of molybdenum, aluminum, etc., or a multi-layer structure of molybdenum, aluminum, etc., but the invention is not limited thereto.

Where the band-pass filter pattern BPF includes a semiconductor material such as silicon germanium (SiGe), the band-pass filter pattern BPF is electrically connected to the first gate electrode GE1. Thus, the band-pass filter pattern BPF may cooperate with the first gate electrode GE1 to serve as a collective gate electrode of the sensing transistor TR1 and a driving capability of the sensing transistor TR1 may be improved.

The first gate electrode GE1 and the band-pass filter pattern BPF are covered by a gate insulating layer 120. The gate insulating layer 120 includes an insulating material, such as silicon nitride (SiNx) or silicon oxide (SiOx). The optical response pattern SP is disposed on the gate insulating layer 120. The optical response pattern SP is disposed on the band-pass filter pattern BPF, and the optical response pattern SP is disposed at a position not overlapped with the first gate electrode GE1 when viewed in a plan view.

The first and second oxide semiconductor patterns OS1 and OS2 are disposed on the optical response pattern SP and spaced apart from each other. The first oxide semiconductor pattern OS1 fully covers an end portion of the optical response pattern SP disposed at one side of the optical response pattern SP and the second oxide semiconductor pattern OS2 fully covers an end portion of the optical response pattern SP disposed at the other (opposing) side of the optical response pattern SP. That is, the first oxide semiconductor pattern OS1 overlaps end portion upper and side surfaces of the optical response pattern SP disposed at one side of the optical response pattern SP, and the second oxide semiconductor pattern OS2 overlaps end portion upper and side surfaces of the optical response pattern SP disposed at the other (opposing) side of the optical response pattern SP. Therefore, in a method of manufacturing the sensor substrate, the first and second oxide semiconductor patterns OS1 and OS2 protect the optical response pattern SP during a subsequent process, e.g., an etching process.

The first source electrode SE1 is disposed on the first oxide semiconductor pattern OS1 and the first drain electrode DE1 is disposed on the second oxide semiconductor pattern OS2. Each of the first source electrode SE1 and the first drain electrode DE1 may have a triple-layer structure of molybdenum, aluminum and molybdenum or a double-layer structure of titanium and copper, but the invention is not limited thereto.

The first source electrode SE1 exposes an edge portion of an upper surface of the first oxide semiconductor pattern OS1 and the first drain electrode DE1 exposes an edge portion of an upper surface of the second oxide semiconductor pattern OS2. The first source electrode SE1 also exposes a portion of the upper surface of the first oxide semiconductor pattern OS1 disposed on the optical response pattern SP and the first drain electrode DE1 exposes a portion of the upper surface of the second oxide semiconductor pattern OS2 disposed on the optical response pattern SP.

Thus, when a distance between the first oxide semiconductor pattern OS1 and the second oxide semiconductor pattern OS2 is referred to as a first distance d1, a second distance d2 between the first source electrode SE1 and the first drain electrode DE1 is greater than the first distance d1.

The first oxide semiconductor pattern OS1 serves as an ohmic contact pattern between the first source electrode SE1 and the optical response pattern SP and the second oxide semiconductor pattern OS2 serves as an ohmic contact pattern between the first drain electrode DE1 and the optical response pattern SP. Particularly, the amorphous silicon germanium (a-SiGe) of the optical response pattern SP has a carrier density in a range from about 10E17 to about 10E18, which is many times, e.g., about 100 times to about 1000 times, greater than that of the amorphous silicon (a-Si), and thus the amorphous silicon germanium (a-SiGe) serves as the ohmic contact pattern.

Especially, when the sensing transistor TR1 uses a cut-off current (Ioff) characteristic, the function of the ohmic contact pattern may be not critical since the carrier density does not exert influence on the cut-off current (Ioff) characteristic. Thus, in the exemplary embodiments in which the sensing transistor TR1 uses the cut-off current (I-off) characteristic, the first and second oxide semiconductor patterns OS1 and OS2 may serve as the ohmic contact pattern. Where the first and second oxide semiconductor patterns OS1 and OS2 serve as the ohmic contact pattern, the sensing transistor TR1 does not to include an additional ohmic contact pattern.

The switching transistor TR2 may be configured to have a thin film transistor including a third oxide semiconductor pattern OS3 as a channel layer thereof As an example, the third oxide semiconductor pattern OS3 may include an amorphous oxide material, e.g., In—Ga—Zn—O, or a polycrystalline material, e.g., ZnO.

The switching transistor TR2 further includes a second gate electrode GE2, a second source electrode SE2 and a second drain electrode DE2. The second gate electrode GE2 is disposed on the base substrate 110 and covered by the gate insulating layer 120. The second gate electrode GE2 may have a single-layer structure of molybdenum, aluminum, etc., or a multi-layer structure of molybdenum, aluminum, etc., but the invention is not limited thereto. The third oxide semiconductor pattern OS3 is disposed on the gate insulating layer 120 to face the second gate electrode GE2 while the gate insulating layer 120 is interposed between the second gate electrode GE2 and the third oxide semiconductor pattern OS3. The third oxide semiconductor pattern OS3 may have a size greater than that of the second gate electrode GE2, when viewed in the plan view.

The second source electrode SE2 and the second drain electrode DE2 are disposed on the third oxide semiconductor pattern OS3. The second source electrode SE2 and the second drain electrode DE2 are spaced apart from each other on the third oxide semiconductor pattern OS3.

Although not shown in figures, the sensor substrate 100 may further include a protection layer to cover the sensing transistor TR1 and the switching transistor TR2. The protection layer may include an insulating material.

FIG. 2 is a cross-sectional view showing another exemplary embodiment of a sensor substrate according to the invention. In FIG. 2, the same reference numerals denote the same elements in FIG. 1, and thus the detailed descriptions of the same elements will be omitted.

Referring to FIG. 2, a sensor substrate 101 includes a base substrate 110, and a sensing transistor TR1 and a switching transistor TR2 which are disposed on the base substrate 110. The sensing transistor TR1 is electrically connected to the switching transistor TR2 to form a sensor, and the sensor may further include a capacitor (not shown) connected to the sensing transistor TR1 and the switching transistor TR2.

The sensing transistor TR1 further includes a first ohmic contact pattern OT1 and a second ohmic contact pattern OT2. The first and second ohmic contact patterns OT1 and OT2 are disposed on the upper surface of the optical response pattern SP and spaced apart from each other on the optical response pattern SP. The first ohmic contact pattern OT1 is disposed between the first oxide semiconductor pattern OS1 and the optical response pattern SP and the second ohmic contact pattern OT2 is disposed between the second oxide semiconductor pattern OS2 and the optical response pattern SP.

As an exemplary embodiment, the first and second ohmic contact patterns OT1 and OT2 may include n+amorphous silicon (a-Si) doped with high concentration of an n-type impurity, e.g., phosphorous (P).

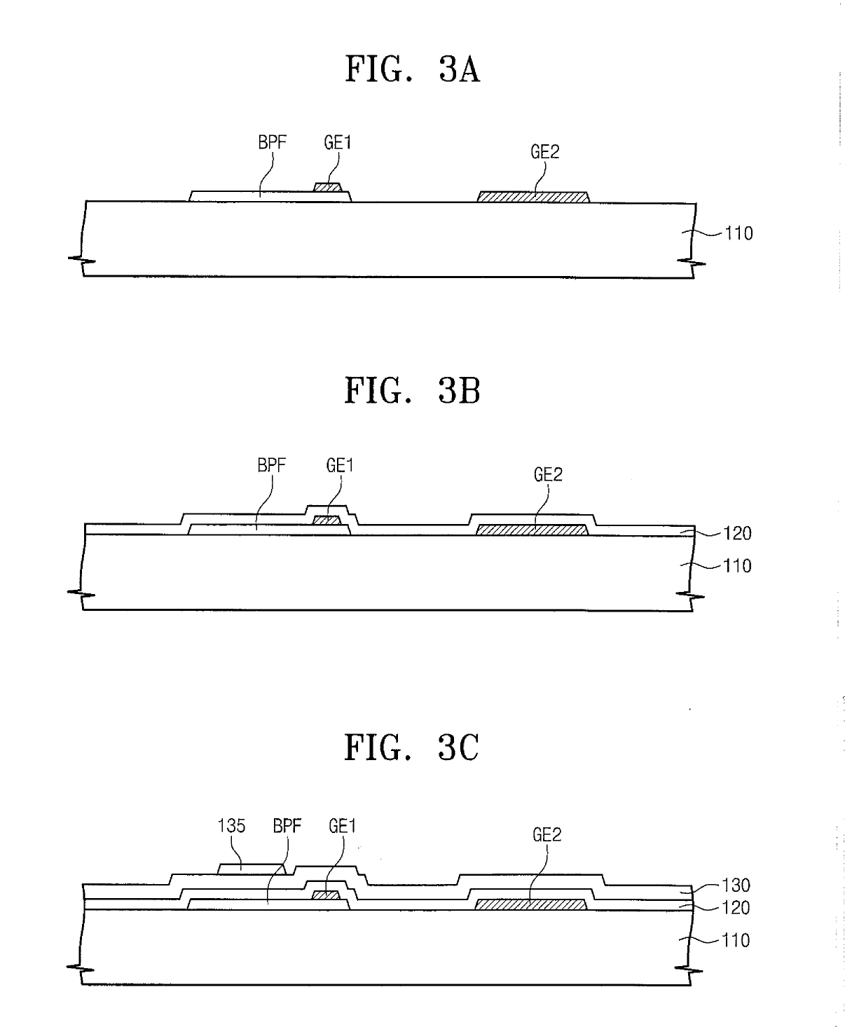

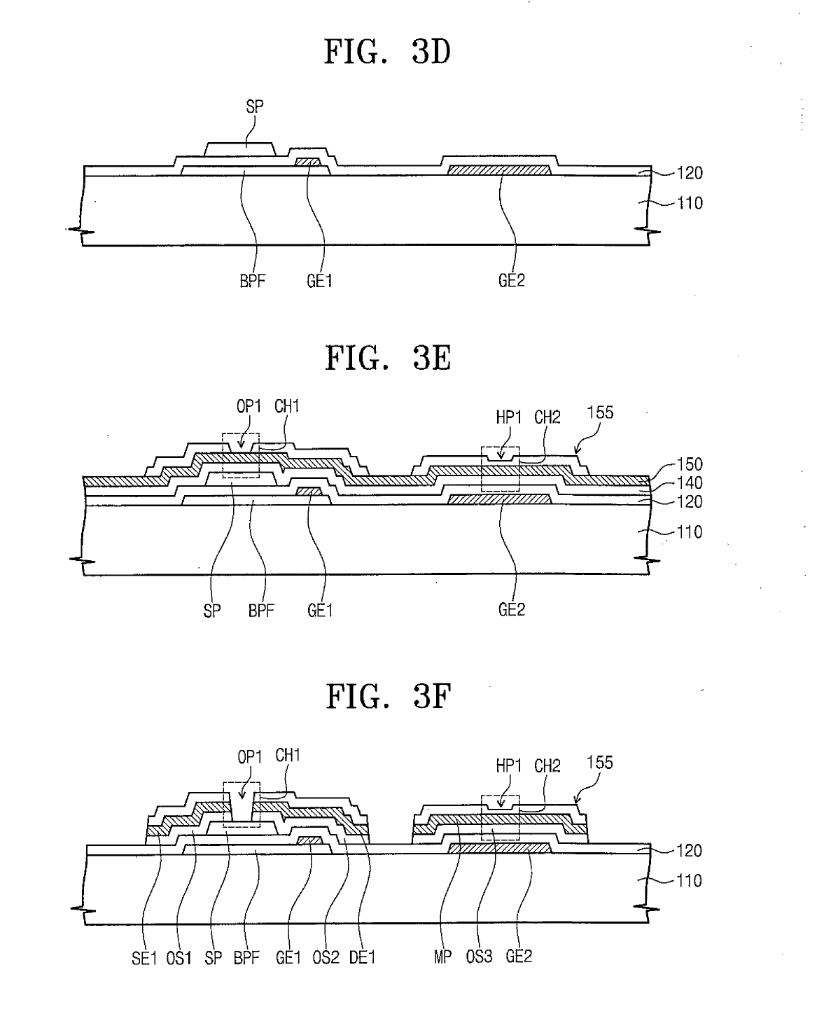

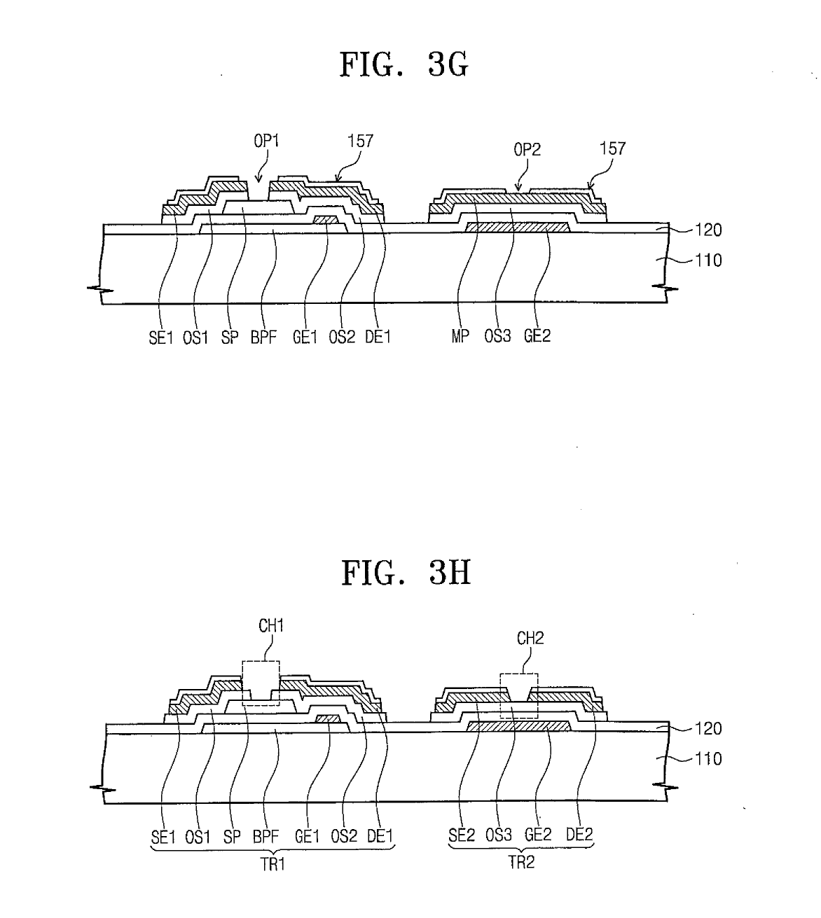

FIGS. 3A to 3H are cross-sectional views showing an exemplary embodiment of a manufacturing process of the sensor substrate shown in FIG. 1.

Referring to FIG. 3A, the band-pass filter pattern BPF is formed on the base substrate 110. The band-pass filter pattern BPF includes a filtering material which blocks the visible light among lights provided from outside the sensor substrate. In an exemplary embodiment, for instance, the band-pass filter pattern BPF may include the organic material having the black pigment, amorphous silicon (a-Si), amorphous germanium (a-Ge) or amorphous silicon germanium (a-SiGe).

A first metal layer (not shown) is formed o the band-pass filter pattern BPF. The first metal layer has a single-layer structure of molybdenum, aluminum, etc., or a multi-layer structure of molybdenum, aluminum, etc., but the invention is not limited thereto. The first metal layer is patterned to form the first gate electrode GEl on the band-pass filter pattern BPF, and to form the second gate electrode GE2 on the base substrate 110 and spaced apart from the band-pass filter pattern BPF when viewed in the plan view.

Referring to FIG. 3B, the gate insulating layer 120 is formed to cover the band-pass filter pattern BPF, the first gate electrode GEl and the second gate electrode GE2. The gate insulating layer 120 includes an insulating material, such as silicon nitride (SiNx) or silicon oxide (SiOx). The gate insulating layer 120 has a single-layer structure of silicon nitride (SiNx) or a double-layer structure of silicon nitride (SiNx) and silicon oxide (SiOx), but the invention is not limited thereto.

Referring to FIGS. 3C and 3D, an optical response layer 130 is formed on the gate insulating layer 120. As an exemplary embodiment, the optical response layer 130 includes amorphous germanium (a-Ge) or amorphous silicon germanium (a-SiGe). A first photosensitive pattern 135 is formed on the optical response layer 130. The first photosensitive pattern 135 is formed on (e.g., overlapping) the band-pass filter pattern BPF.

The optical response layer 130 is etched by a dry etching process using the first photosensitive pattern 135 as a mask. When the first photosensitive pattern 135 is stripped after the etching process is finished, the optical response pattern SP is formed on the gate insulating layer 120.

After the optical response pattern SP is formed, a plasma oxidation process is performed on the optical response pattern SP to oxidize a surface of the optical response pattern SP. The gate insulating layer 120 may be exposed to the plasma oxidation process. Where the gate insulating layer 120 includes silicon nitride, the plasma oxidation process performed on the gate insulating layer 120 also forms a silicon oxide layer.

Referring to FIG. 3E, an oxide semiconductor layer 140 and a second metal layer 150 are sequentially stacked on the optical response pattern SP and the gate insulating layer 120. The oxide semiconductor layer 140 includes the amorphous oxide material, e.g., indium-gallium-zinc-oxide (In—Ga—Zn—), or the polycrystalline material, e.g., zinc oxide (ZnO). The second metal layer 150 has a triple-layer structure of molybdenum, aluminum, and molybdenum or a double-layer structure of titanium and copper, but the invention is not limited thereto.

A second photosensitive pattern 155 is formed on the second metal layer 150. The second photosensitive pattern 155 includes a first opening portion OP1 formed therethrough to correspond to a first channel area CH1 defined between the first source electrode SE1 and the first drain electrode DE1 and a first half-tone portion HP1 formed corresponding to a second channel area CH2 defined between the second source electrode SE2 and the second drain electrode DE2. The first opening portion OP1 corresponds to an area where the second photosensitive pattern 155 is opened, and a portion of an upper surface of the second metal layer 150 is exposed through the first opening portion OP1 in the first channel area CH1. The first half-tone portion HP1 corresponds to an area where a thickness of the second photosensitive pattern 155 is partially reduced and smaller than an adjacent thickness thereof, and the portion of the upper surface of the second metal layer 150 is not exposed in the second channel area CH2.

The second metal layer 150 and the oxide semiconductor layer 140 are etched using the second photosensitive pattern 155 as a mask. The second metal layer 150 and the oxide semiconductor layer 140 may be substantially and simultaneously etched through a wet etching process. Accordingly, as shown in FIG. 3F, the first oxide semiconductor pattern OS1 and the second oxide semiconductor pattern OS2 are formed on the optical response pattern SP, and the first source electrode SE1 and the first drain electrode DE1 are formed on the first oxide semiconductor pattern OS1 and the second oxide semiconductor pattern OS2, respectively. In addition, the third oxide semiconductor pattern OS3 is formed on the gate insulating layer 120 to face the second gate electrode GE2, and a metal pattern MP is disposed on the third oxide semiconductor pattern OS3. Since the third oxide semiconductor pattern OS3 and the metal pattern MP are substantially and simultaneously etched, the third oxide semiconductor pattern OS3 and the metal pattern MP have the same shape.

Referring to FIG. 3G, the second photosensitive pattern 155 is etched back to form a third photosensitive pattern 157. The third photosensitive pattern 157 includes a second opening portion OP2 formed therethrough to expose the metal pattern MP corresponding to the second channel area CH2. In the etch-back process, a width of the first opening portion OP1 may increase after the etch-back process.

The first source electrode SE1, the first drain electrode DE1 and the metal pattern MP are wet etched using the third photosensitive pattern 157 as a mask. Therefore, as shown in

FIG. 3H, the second distance d2 (refer to FIG. 1) between the first source electrode SE1 and the first drain electrode DE1 becomes greater than the first distance dl between the first oxide semiconductor pattern OS1 and the second oxide semiconductor pattern OS2. Also, the second source electrode SE2 and the second drain electrode DE2 are formed on the third oxide semiconductor pattern OS3, and the second source electrode SE2 and the second drain electrode DE2 are spaced apart from each other in the second channel area CH2.

The wet-etched first source electrode SE1 exposes an edge portion of an upper surface of the first oxide semiconductor pattern OS1 and the wet-etched first drain electrode DE1 exposes an edge portion of an upper surface of the second oxide semiconductor pattern OS2. The wet-etched first source electrode SE1 also exposes a portion of the upper surface of the first oxide semiconductor pattern OS1 disposed on the optical response pattern SP and the wet-etched first drain electrode DE1 exposes a portion of the upper surface of the second oxide semiconductor pattern OS2 disposed on the optical response pattern SP.

After that, the third photosensitive pattern 157 is stripped to complete the sensing transistor TR1 and the switching transistor TR2 on the base substrate 110 as shown in FIG. 1.

The optical response pattern SP is formed prior to the third oxide semiconductor pattern OS3 by patterning the optical response layer 130 through the dry etching process, and the third oxide semiconductor pattern OS3, which is patterned using the wet etching process, serves as the channel layer in the switching transistor TR2. Thus, a manufacturing process of the sensor substrate 100 may be simplified and a yield thereof may be increased.

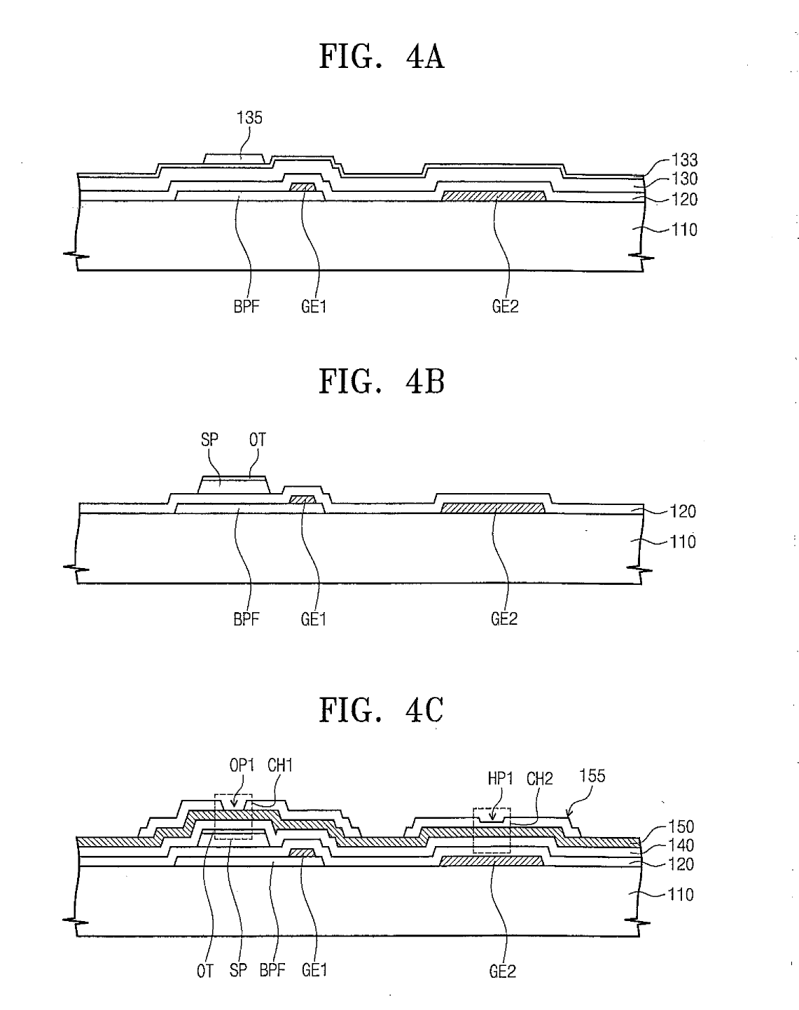

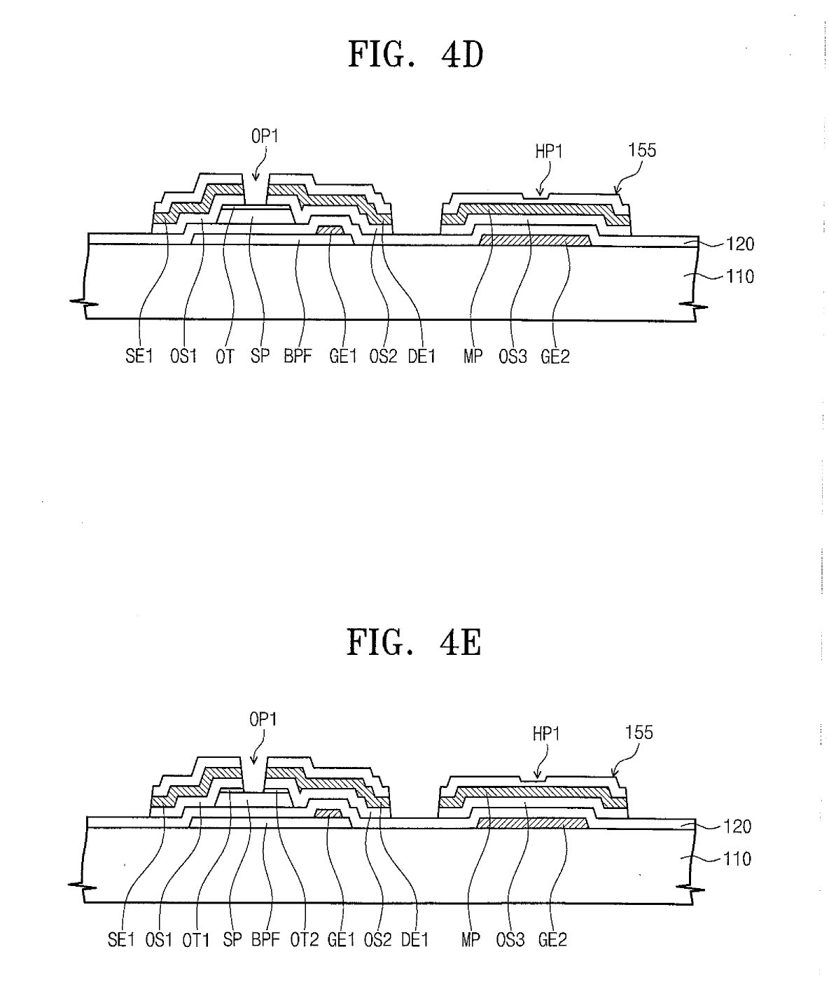

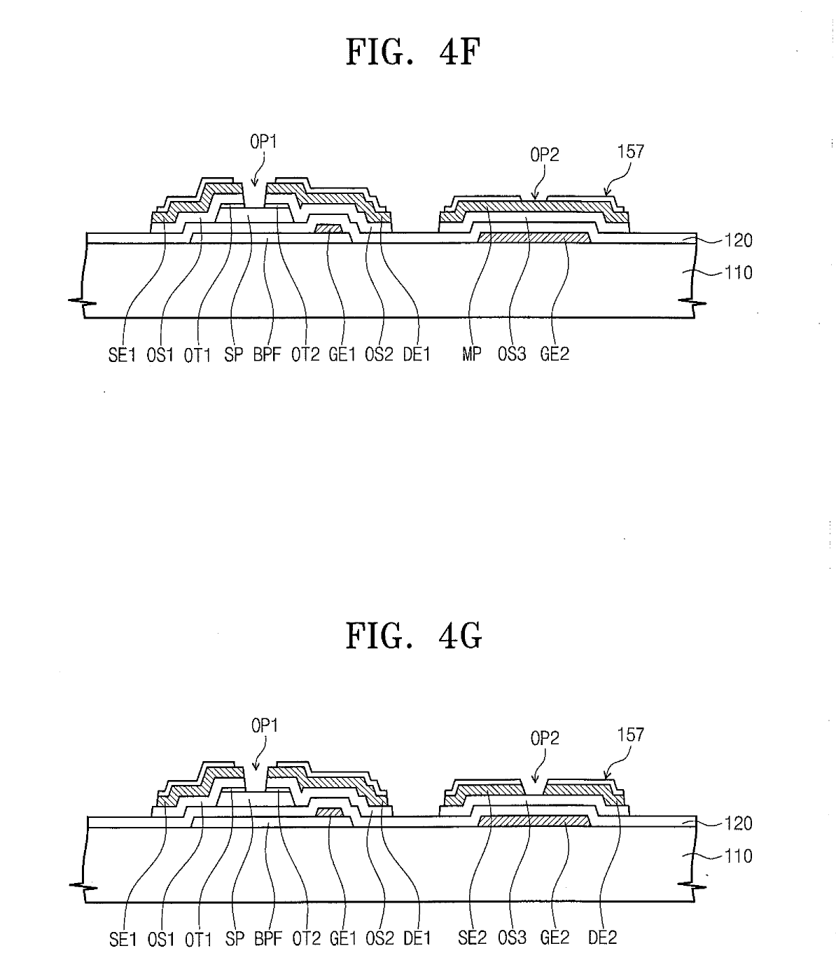

FIGS. 4A to 4G are cross-sectional views showing an exemplary embodiment of a manufacturing process of the sensor substrate of FIG. 2. In the exemplary embodiment, the manufacturing processes prior to FIG. 4A are substantially the same as those shown in FIGS. 3A to 3B, and thus detailed descriptions of the same processes will be omitted. Referring to FIG. 4A, an optical response layer 130 and an ohmic contact layer 133 are formed on the gate insulting layer 120. The optical response layer 130 includes amorphous germanium (a-Ge) or amorphous silicon germanium (a-SiGe), and the ohmic contact layer 133 includes n+amorphous silicon (a-Si).

A first photosensitive pattern 135 is formed on the ohmic contact layer 133. The optical response layer 130 and the ohmic contact layer 133 are etched by a dry etching process using the first photosensitive pattern 135 as a mask. When the first photosensitive pattern 135 is stripped after the etching process, the optical response pattern SP is formed on the gate insulating layer 120 and an ohmic contact pattern OT is formed on the optical response pattern SP as shown in FIG. 4B.

Referring to FIG. 4C, an oxide semiconductor layer 140 and a second metal layer 150 are sequentially stacked on the ohmic contact pattern OT and the gate insulating layer 120. The oxide semiconductor layer 140 includes an amorphous oxide material e.g., indium-gallium-zinc-oxide (In—Ga—Zn—O) or a polycrystalline material, e.g., zinc oxide (ZnO).

A second photosensitive pattern 155 is formed on the second metal layer 150. The second photosensitive pattern 155 includes a first opening portion OP1 formed therethrough corresponding to a first channel area CH1 defined between the first source electrode SE1 and the first drain electrode DE1 and a first half-tone portion HP1 formed corresponding to a second channel area CH2 defined between the second source electrode SE2 and the second drain electrode DE2.

The second metal layer 150 and the oxide semiconductor layer 140 are substantially and simultaneously wet etched using the second photosensitive pattern 155 as a mask. Accordingly, as shown in FIG. 4D, a first oxide semiconductor pattern OS1 and a second oxide semiconductor pattern OS2 are formed on the ohmic contact pattern OT, and the first source electrode SE1 and the first drain electrode DE1 are formed on the first oxide semiconductor pattern OS1 and the second oxide semiconductor pattern OS2, respectively. The second metal layer 140 and the oxide semiconductor layer 150 are removed in an area corresponding to the first opening portion OP1, and thus an upper surface of the ohmic contact pattern OT disposed in the first channel area CH1 is exposed.

The second photosensitive pattern 155 has an area greater than that of the optical response pattern SP. Thus, the first oxide semiconductor pattern OS1 fully covers an edge portion disposed at one side of the optical response pattern SP, and the second oxide semiconductor pattern OS2 fully covers an edge portion disposed at the other side of the optical response pattern SP.

In addition, a third oxide semiconductor pattern OS3 is formed on the gate insulating layer 120 to face the second gate electrode GE2, and a metal pattern MP is disposed on the third oxide semiconductor pattern OS3.

Then, the ohmic contact pattern OT disposed between the first oxide semiconductor pattern OS1 and the second oxide semiconductor pattern OS2 in the first channel area CH1 is etched by a dry etching process using the second photosensitive pattern 155 as a mask. As shown in FIG. 4E, a first ohmic contact pattern OT1 is formed between the first oxide semiconductor pattern OS1 and the optical response pattern SP and a second ohmic contact pattern OT2 is formed between the second oxide semiconductor pattern OS2 and the optical response pattern SP.

Referring to FIG. 4F, the second photosensitive pattern 155 is etched back to form a third photosensitive pattern 157. The third photosensitive pattern 157 includes a second opening portion OP2 formed therethrough to expose the metal pattern MP corresponding to the second channel area CH2 on the third oxide semiconductor pattern OS3. In the etch-back process, a width of the first opening portion OP1 may increase after the etch-back process.

Referring to FIG. 4G, the first source electrode SE1, the first drain electrode DE1 and the metal pattern MP are wet etched using the third photosensitive pattern 157 as a mask. Then, the second distance d2 (refer to FIG. 1) between the first source electrode SE1 and the first drain electrode DE1 becomes greater than the first distance d1 (refer to FIG. 1) between the first oxide semiconductor pattern OS1 and the second oxide semiconductor pattern OS2 as shown in FIG. 2.

In addition, the second source electrode SE2 and the second drain electrode DE2 are formed on the third oxide semiconductor pattern OS3, and the second source electrode SE2 and the second drain electrode DE2 are disposed to be spaced apart from each other in the second channel area CH2.

The wet-etched first source electrode SE1 exposes an edge portion of an upper surface of the first oxide semiconductor pattern OS1 and the wet-etched first drain electrode DE1 exposes an edge portion of an upper surface of the second oxide semiconductor pattern OS2. The wet-etched first source electrode SE1 also exposes a portion of the upper surface of the first oxide semiconductor pattern OS1 disposed on the optical response pattern SP and the wet-etched first drain electrode DE1 exposes a portion of the upper surface of the second oxide semiconductor pattern OS2 disposed on the optical response pattern SP.

Then, when the third photosensitive pattern 157 is stripped, the sensing transistor TR1 and the switching transistor TR2 are completed on the base substrate 110 as shown in FIG. 2.

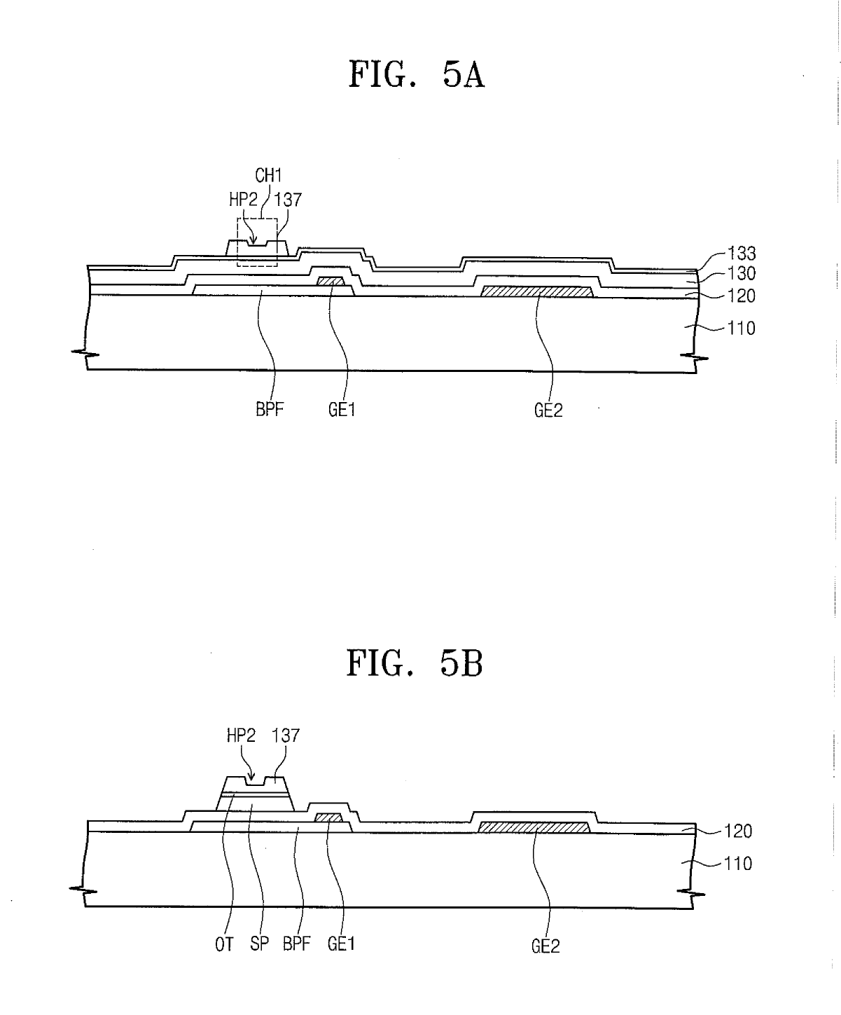

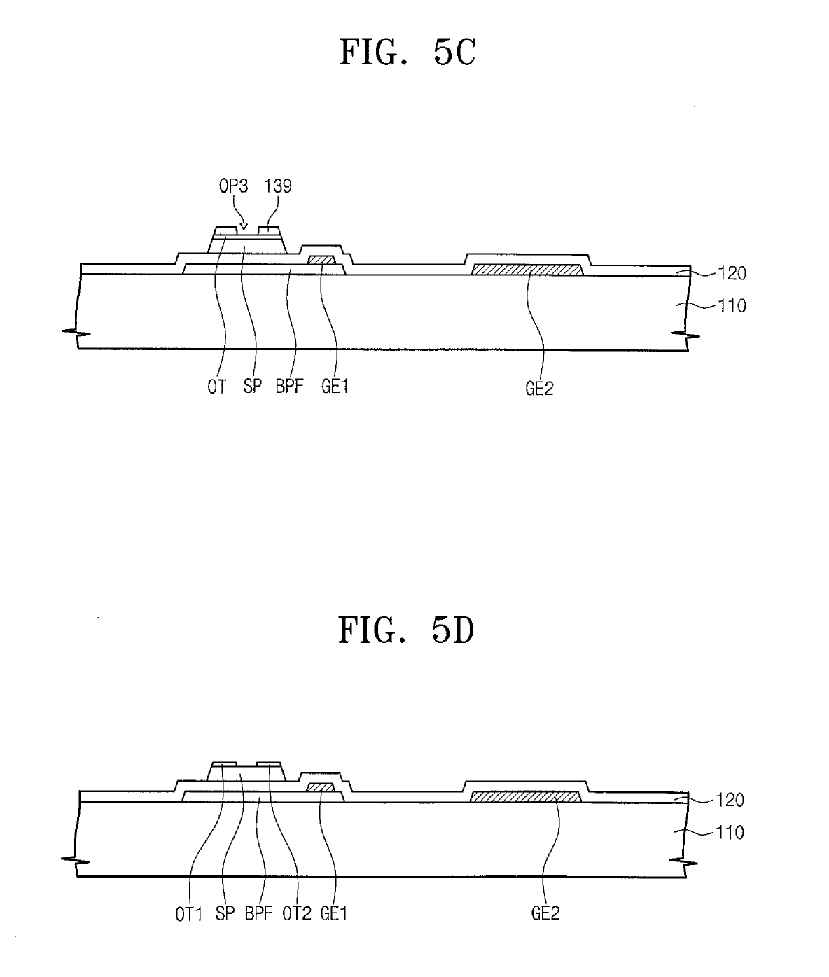

FIGS. 5A to 5D are cross-sectional views showing another exemplary embodiment of a manufacturing process of the sensor substrate shown in FIG. 2 according to the invention. In the exemplary embodiment, the manufacturing processes prior to FIG. 5A are substantially the same as the manufacturing process shown in FIGS. 3A and 3B, and thus detailed descriptions of the same processes will be omitted.

Referring to FIG. 5A, an optical response layer 130 and an ohmic contact layer 133 are formed on the gate insulating layer 120. The optical response layer 130 includes amorphous silicon germanium (a-SiGe), and the ohmic contact layer 133 includes n+amorphous silicon (a-Si).

A fourth photosensitive pattern 137 is formed on the ohmic contact layer 133. The fourth photosensitive pattern 137 includes a second half-tone portion HP2 in the first channel area CH1. The optical response layer 130 and the ohmic contact layer 133 are etched by a dry etching process using the fourth photosensitive pattern 137 as a mask. As shown in FIG. 5B, when the etching process is finished, an optical response pattern SP is formed on the gate insulating layer 120 and an ohmic contact pattern OT is formed on the optical response pattern SP.

Then, the fourth photosensitive pattern 137 is etched back to form a fifth photosensitive pattern 139 on the ohmic contact pattern OT as shown in FIG. 5C. The fifth photosensitive pattern 139 includes a third opening portion OP3 formed therethrough to expose the ohmic contact pattern OT corresponding to the first channel area CH1.

The exposed ohmic contact pattern OT is etched using the fifth photosensitive pattern 139 as a mask, and a first ohmic contact pattern OT1 and a second ohmic contact pattern OT2 are formed on the optical response pattern SP as shown in FIG. 5D. Then, the fifth photosensitive pattern 139 on the first and second ohmic contact patterns OT1 and OT2 is stripped.

Since the manufacturing processes following the process shown in FIG. 5D are substantially the same as the manufacturing processes described with reference to FIGS. 3E to 3H, detailed descriptions of the same processes will be omitted.

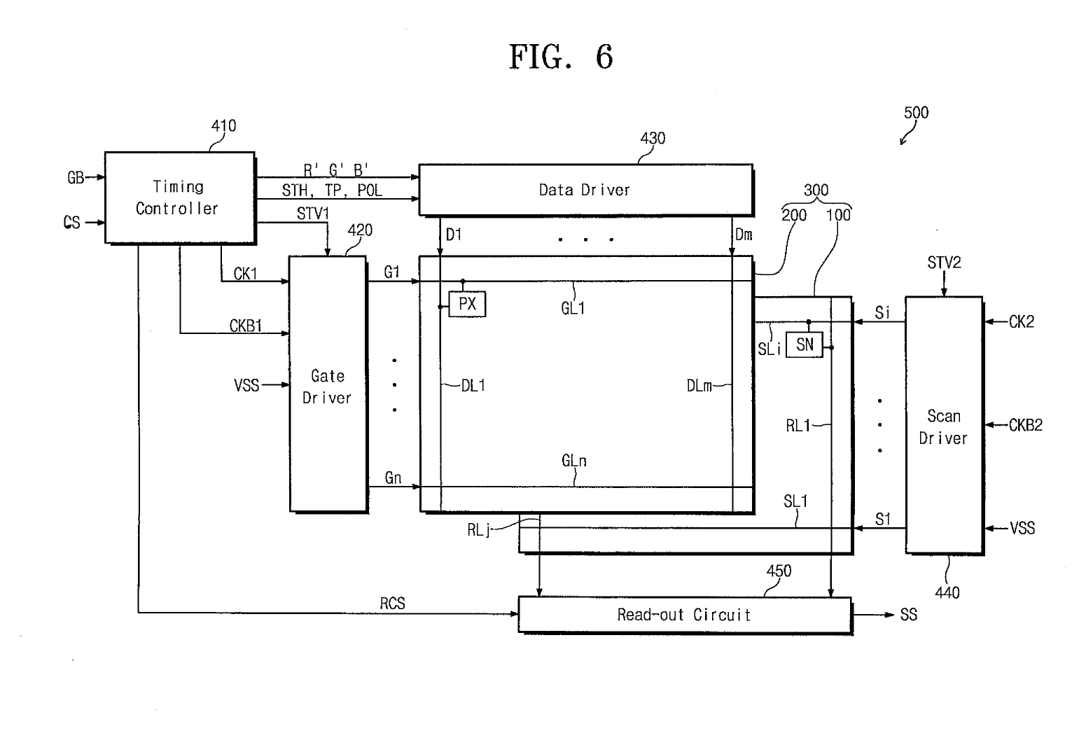

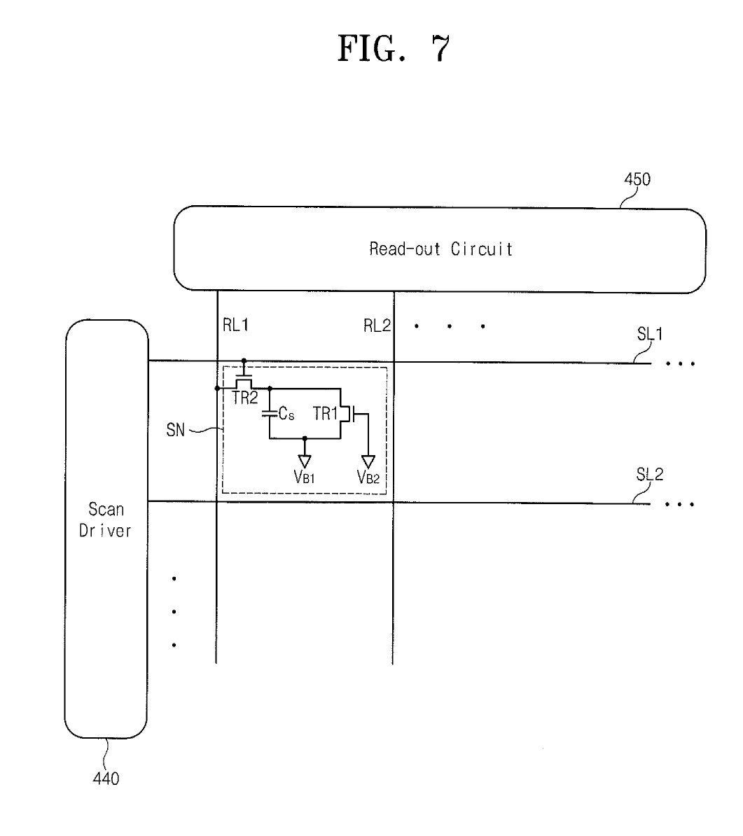

FIG. 6 is a block diagram showing an exemplary embodiment of a display apparatus according to the invention, and FIG. 7 is a circuit diagram showing an exemplary embodiment of a plurality of sensors of a display apparatus such as shown in FIG. 6.

Referring to FIG. 6, a display apparatus 500 includes a display panel 300, a timing controller 410, a gate driver 420, a data driver 430, a scan driver 440 and a read-out circuit 450.

The timing controller 410 receives image signals RGB and control signals CS from outside the display apparatus 500. The timing controller 410 converts a data format of the image signals RGB to a data format appropriate to an interface between the data driver 430 and the timing controller 410 and provides the converted image signals R′G′B′ to the data driver 430. The timing controller 410 applies a data control signal, e.g., an output start signal TP, a horizontal start signal STH, a polarity inversion signal POL, etc., to the data driver 430 and applies a gate control signal, e.g., a first start signal STV1, a first clock signal CK1, a second clock signal CKB1, etc., to the gate driver 420.

The gate driver 420 sequentially outputs gate signals G1 to Gn in response to the gate control signal STV1, CK1 and CKB1 provided from the timing controller 410. The data driver 430 converts the image signals R′G′B′ to data voltages D1 to Dm in response to the data control signal TP, STH and POL provided from the timing controller 410 and outputs the data voltages D1 to Dm. The data voltages D1 to Dm are applied to the display panel 300.

The display panel 300 includes a pixel substrate 200, a sensor substrate 100 facing the pixel substrate 200, and a light control layer (not shown) interposed between the pixel substrate 200 and the sensor substrate 100. The pixel substrate 200 includes a plurality of pixels PX disposed thereon, and the sensor substrate 100 includes a plurality of sensors SN disposed thereon.

In the exemplary embodiment, the pixels PX have the same structure and function, and thus only one pixel will be described in detail as a representative example.

The pixel substrate 200 includes a plurality of gate lines GL1 to GLn, a plurality of data lines DL1 to DLm crossing the gate lines GL1 to GLn, and the pixels PX. Each pixel PX includes a pixel transistor (not shown) and a pixel electrode (not shown). The pixel transistor includes a gate electrode connected to a corresponding gate line of the gate lines GL1 to GLn, a source electrode connected to a corresponding data line of the data lines DL1 to DLm, and a drain electrode connected to the pixel electrode.

The gate lines GL1 to GLn are connected to the gate driver 420 and the data lines DL1 to DLm are connected to the data driver 430. The gate lines GL1 to GLn receive the gate signals G1 to Gn provided from the gate driver 420, and the data lines DL1 to DLm receive the data voltages D1 to Dm provided from the data driver 430.

Accordingly, the pixel transistor of each pixel PX is turned on in response to the gate signal provided through the corresponding gate line, and the data voltage provided through the corresponding data line is applied to the pixel electrode through the turned-on pixel transistor.

Although not shown in figures, the sensor substrate 100 may include a reference electrode, which faces the pixel electrode such that the light control layer is interposed between the reference electrode and the pixel electrode. According to another exemplary embodiment, the reference electrode may be disposed on the pixel substrate.

The sensor substrate 100 includes a plurality of scan lines SL1 to SLi, a plurality of read-out lines RL1 to RLj crossing the scan lines SL1 to SLi, and the sensors SN. The sensors SN may be uniformly arranged over the entire surface of the sensor substrate 100 to sense the infrared light incident to the display panel 300.

The scan lines SL1 to SLi are connected to the scan driver 440 to sequentially receive scan signals S1 to Si. The scan driver 440 receives a scan control signal, e.g., a second start signal STV2, a third clock signal CK2, a fourth scan signal CKB2, etc., to sequentially output the scan signals S1 to Si. The scan control signal STV2, CK2 and CKB2 may be synchronized to the gate control signal STV1, CK1 and CKB1 but the invention is not limited thereto.

The read-out lines RL1 to RLj are connected to the read-out circuit 450 to provide voltages charged to corresponding sensors SN to the read-out circuit 450.

For the convenience of explanation, FIG. 7 shows a first scan line SL1 and a second scan line SL2 among the scan lines SL1 to SLi and a first read-out line RL1 and a second read-out line RL2 among the read-out lines RL1 to RLj.

Referring to FIG. 7, each of the sensors SN includes a sensing transistor TR1, a switching transistor TR2 and a capacitor Cs. The switching transistor TR2 includes a second gate electrode connected to a corresponding first scan line SL1 among the scan lines SL1 to SLi, a second source electrode connected a corresponding first read-out line RL1 of the read-out lines RL1 to RLj, and a second drain electrode connected to the capacitor Cs and the sensing transistor TR1.

The capacitor Cs includes a first electrode connected to the second drain electrode of the switching transistor TR2 and a second electrode applied with a first bias voltage V_{B1}. In an exemplary embodiment, for instance, the first bias voltage V_{B1} has a voltage level of about −8.75 volts (V).

The sensing transistor TR1 includes a first gate electrode applied with a second bias voltage V_{B2}, a first source electrode connected to the second drain electrode of the switching transistor TR2, and a second drain electrode applied with the first bias voltage V_{B1}. The second bias voltage V_{B2} has a voltage level lower than that of the first bias voltage V_{B1}. In an exemplary embodiment, for instance, the second bias voltage V_{B2} has a voltage level of about −13.75 V.

The sensing transistor TR1 generates a photo current corresponding to an amount of light incident thereto from outside thereof. The light may have an infrared light wavelength. The level of the voltage charged in the capacitor Cs increases by the photo current generated by the sensing transistor TR1. That is, the voltage charged in the capacitor Cs increases as the amount of light incident to the sensing transistor TR1 increases. Therefore, the sensing transistor TR1 may sense the light.

When the switching transistor TR2 is turned on in response to the scan signal provided through the corresponding scan line, each sensor SN provides the voltage charged in the capacitor Cs to the corresponding read-out line through the turned-on switching transistor TR2.

The read-out circuit 450 sequentially applies voltages SS provided from the read-out lines RL1 to RLj to the timing controller 410 in response to control signals RCS from the timing controller 410. The timing controller 410 may generate a two-dimensional coordinate value indicating a position at which a touch event occurs based on an output timing of the scan signal and the voltage SS from the read-out circuit 450. As a result, the timing controller 410 may detect position information at which the infrared light is sensed.

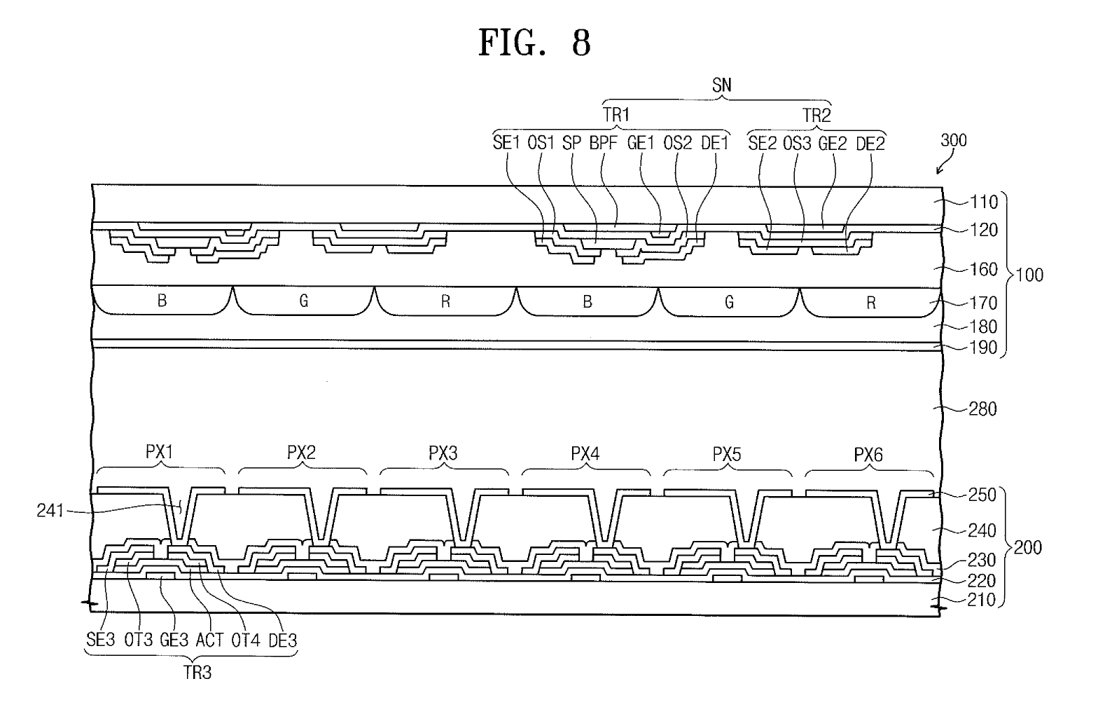

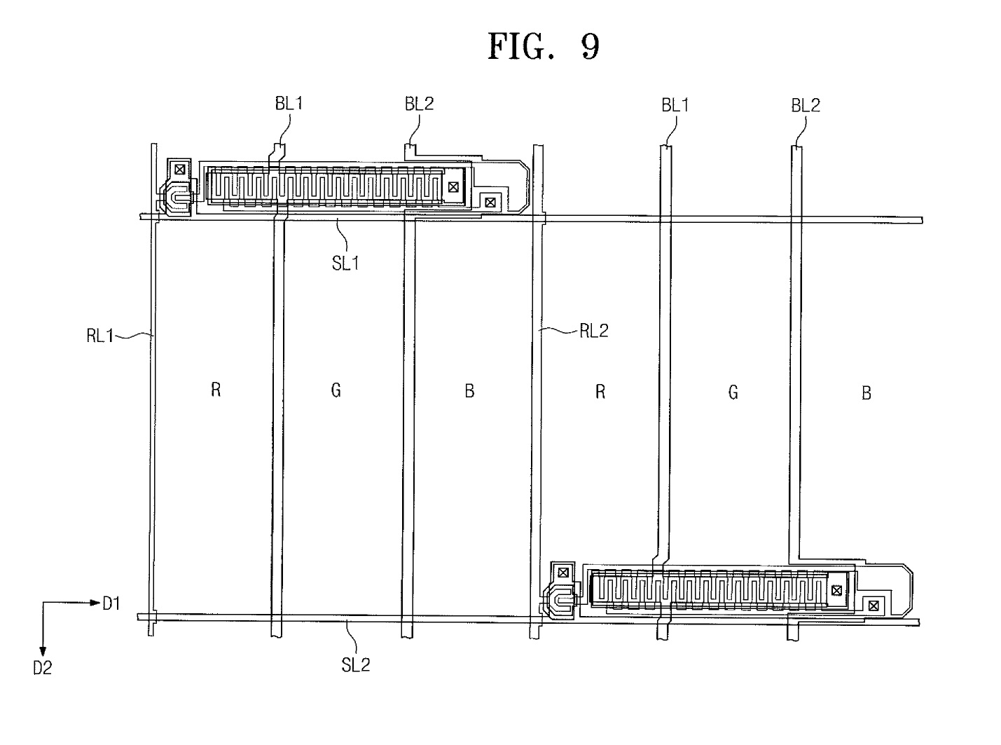

FIG. 8 is a cross-sectional view showing an exemplary embodiment of a display panel such as the display panel shown in FIG. 6.

Referring to FIG. 8, the display panel 300 includes the pixel substrate 200, the sensor substrate 100 facing the pixel substrate 200, and a light control layer 280 such as a liquid crystal layer interposed between the pixel substrate 200 and the sensor substrate 100.

The sensor substrate 100 includes a first base substrate 110, the sensors SN, a color filter layer 170 including a plurality of color pixels R, G and B disposed to respectively correspond to the pixels PX, and a reference electrode 190. Since the structure of the sensors SN has been described in detail with reference to FIGS. 1 to 5D, detailed descriptions of the sensors SN will be omitted.

The sensor substrate 100 further includes a protection layer 160 to cover the sensing transistor TR1 and the switching transistor TR2. The color filter layer 170 is disposed on the protection layer 160. The color filter layer 170 includes a red color pixel R, a green color pixel G and a blue color pixel B, and the red, green and blue color pixels R, G and B are disposed to correspond to the pixels PX in a one-to-one correspondence.

An overcoat layer 180 is disposed on the color filter layer 170. The protection layer 160 and the overcoat layer 180 include an organic insulating material to compensate for a step difference caused by elements disposed thereunder. The reference electrode 190 is disposed on the overcoat layer 180.

The pixel substrate 200 includes a second base substrate 210 and the pixels PX disposed on the second base substrate 210. Each of the pixels PX includes a pixel transistor TR3 and a pixel electrode 250.

FIG. 8 shows six pixels PX1 to PX6, which are sequentially arranged in one direction. In the exemplary embodiment, the six pixels PX1 to PX6 have the same structure and function, and thus only one pixel will be described in detail and details of the other pixels will be omitted.

A third gate electrode GE3 of the pixel transistor TR3 is disposed on the second base substrate 210. The third gate electrode GE3 is covered by a second gate insulating layer 220.

An active layer ACT is disposed on the second gate insulating layer 220 to face the third gate electrode GE3, and a third ohmic contact pattern OT3 and a fourth ohmic contact pattern OT4 are disposed on the active layer ACT. A third source electrode SE3 and a third drain electrode DE3 are disposed on the third ohmic contact pattern OT3 and the fourth ohmic contact pattern OT4, respectively. The third source electrode SE3 and the third drain electrode DE3 are covered by a first insulating layer 230. A second insulating layer 240 may be further disposed on the first insulating layer 230.

A contact hole 241 is defined in the first and second insulating layers 230 and 240 to expose the third drain electrode DE3. The pixel electrode 250 is disposed on the second insulating layer 240 and electrically connected to the third drain electrode DE3 through the contact hole 241.

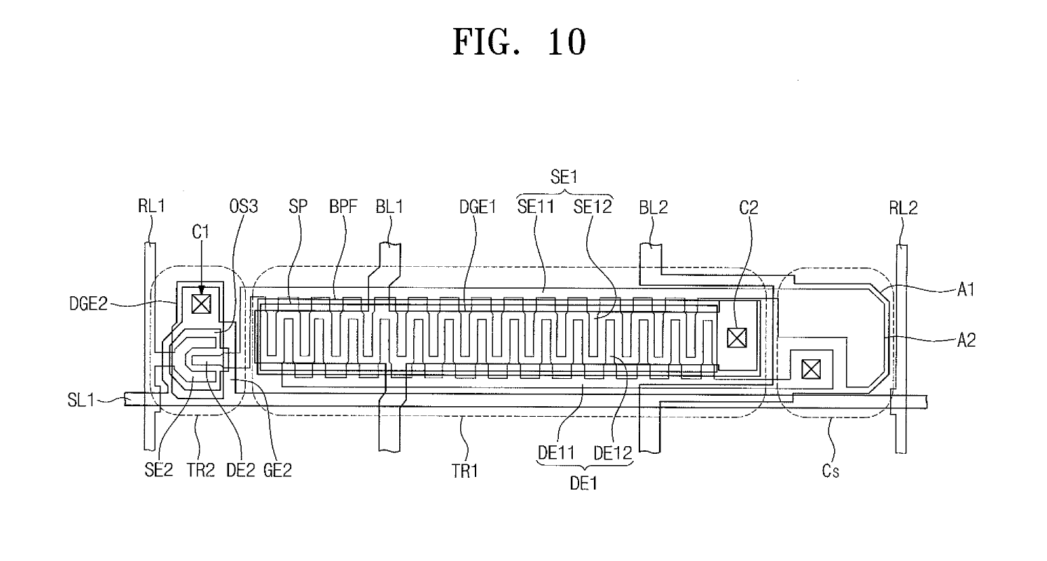

FIG. 9 is a plan view showing an exemplary embodiment of a sensor substrate of a display panel such as the display panel shown in FIG. 8, and FIG. 10 is an enlarged plan view showing an exemplary embodiment of a sensor such as the sensor shown in FIG. 9. Referring to FIG. 9, the sensor substrate 100 includes a first scan line SL1 and a second scan line SL2, which extend in a first direction D1, a first read-out line RL1 and a second read-out line RL2, which extend in a second direction D2 substantially perpendicular to the first direction D1, and a first bias line BL1 and a second bias line BL2, which extend in the second direction D2. The first bias line BL1 receives a first bias voltage V_{B1} from an external source (not shown) and the second bias line BL2 receives a second bias voltage V_{B2} lower than the first bias voltage V_{B1} from the external source. When viewed in a plan view, the first and second bias lines BL1 and BL2 are disposed between the first read-out line RL1 and the second read-out line RL2.

The sensor substrate 200 further includes the red color pixel R, the green color pixel G and the blue color pixel B. The red, green, and blue color pixels R, G and B are sequentially arranged in the first direction D1.

As shown in FIG. 10, each of the sensors SN includes the sensing transistor TR1, the switching transistor TR2 and the capacitor Cs.

The switching transistor TR2 includes the second gate electrode GE2 branched from the first scan line SL1, the third oxide semiconductor pattern OS3 disposed on the second gate electrode GE2, the second source electrode SE2 branched from the first read-out line RL1, and the second drain electrode DE2 spaced apart from the second source electrode SE2 on the third oxide semiconductor pattern OS3. Thus, the switching transistor TR2 is turned on in response to the scan signal applied through the first scan line SL1 and outputs a predetermined signal to the first read-out line RL1.

The switching transistor TR2 may further include a second dummy gate electrode DGE2 electrically connected to the second gate electrode GE2 through a first contact hole C1. The sensing transistor TR1 includes the first gate electrode GE1, the optical response pattern SP responsive to light having the infrared wavelength, the first source electrode SE1 extending from and continuous with the second drain electrode DE2 of the switching transistor TR2 and disposed on the optical response pattern SP, and the first drain electrode DE1 spaced apart from the first source electrode SE1 on the optical response pattern SP. The sensing transistor TR1 may further include a first dummy gate electrode DGE1 applied with the first bias voltage V_{B1} through the first bias line BL1 and electrically connected to the first gate electrode GE1 through a second contact hole C2. The first drain electrode DE1 of the sensing transistor TR1 is electrically connected to the second bias line BL2 to receive the second bias voltage V_{B2}.

The first source electrode SE1 of the sensing transistor TR1 includes a first body electrode SE11 extending in the first direction D1 and a plurality of first branch electrodes SE12 branched from the first body electrode SE11 and arranged in the first direction D1. The first branch electrodes SE12 are disposed on (e.g., overlapping) the optical response pattern SP.

The first drain electrode DE1 of the sensing transistor TR1 includes a second body electrode DE11 extending in the first direction D1 and a plurality of second branch electrodes DE12 branched from the second body electrode DE11 and arranged in the first direction D1. The second branch electrodes DE12 are disposed on (e.g., overlapping) the optical response pattern SP.

The first branch electrodes SE12 are alternately arranged with the second branch electrodes DE12 along the first direction D1. That is, one second branch electrode DE12 is disposed between two first branch electrodes SE12 adjacent to each other.

The capacitor Cs includes a first electrode A1 extending from the second bias line BL2, and a second electrode A2 extending from the first source electrode SE1 of the sensing transistor TR1 and facing the first electrode A1.

The sensing transistor TR1 further includes the band-pass filter pattern BPF that is disposed under the optical response pattern SP to filter the light traveling to the optical response pattern SP.

Although exemplary embodiments of the invention have been described, it is understood that the invention should not be limited to these exemplary embodiments but various changes and modifications can be made by one ordinary skilled in the art within the spirit and scope of the invention as hereinafter claimed.

What is claimed is:

1. A sensor substrate comprising:
a base substrate;
a sensing transistor on the base substrate, and comprising:
a first gate electrode;
an optical response pattern on the first gate electrode;
a first source electrode and a first drain electrode, which are on the optical response pattern and spaced apart from each other;
a first oxide semiconductor pattern between the first source electrode and the optical response pattern; and
a second oxide semiconductor pattern between the first drain electrode and the optical response pattern, and
a switching transistor on the base substrate, and comprising:
a second gate electrode;
a third oxide semiconductor pattern on the second gate electrode; and
a second source electrode and a second drain electrode, which are on the third oxide semiconductor pattern and spaced apart from each other.

2. The sensor substrate of claim 1, wherein
the first oxide semiconductor pattern faces upper and side surfaces of a first end portion of the optical response pattern, and
the second oxide semiconductor pattern faces upper and side surfaces of a second end portion of the optical response pattern opposite to the first end portion thereof.

3. The sensor substrate of claim 2, wherein
the first source electrode exposes a portion of an upper surface of the first oxide semiconductor pattern, and
the first drain electrode exposes a portion of an upper surface of the second oxide semiconductor pattern.

4. The sensor substrate of claim 1, wherein the sensing transistor further comprises:
a first ohmic contact pattern between the optical response pattern and the first oxide semiconductor pattern; and
a second ohmic contact pattern between the optical response pattern and the second oxide semiconductor pattern.

5. The sensor substrate of claim 1, wherein the sensing transistor further comprises a band-pass filter pattern which is between the optical response pattern and the base substrate, and filters a visible light.

6. A method of manufacturing a sensor substrate, comprising:
forming a first gate electrode and a second gate electrode on a base substrate;
forming a gate insulating layer to cover the first and second gate electrodes;
forming an optical response layer on the gate insulating layer;
forming a first photosensitive pattern on the optical response layer;
etching the optical response layer using the first photosensitive pattern as a mask to form an optical response pattern of a sensing transistor;
forming an oxide semiconductor layer on the gate insulating layer and the optical response pattern;
forming a metal layer on the oxide semiconductor layer;
forming a second photosensitive pattern on the metal layer;
first etching the oxide semiconductor layer and the metal layer using the second photosensitive pattern as a mask to form:
a first source electrode and a first drain electrode on the first gate electrode, a first oxide semiconductor pattern between the first source electrode and the optical response pattern, a second oxide semiconductor pattern between the first drain electrode and the optical response pattern, of the sensing transistor, and
a metal pattern and a third oxide semiconductor pattern on the second gate electrode, of a switching transistor;
etching back the second photosensitive pattern to form a third photosensitive pattern; and
second etching the metal layer using the third photosensitive pattern as a mask to form a second source electrode and a second drain electrode, which are on the third oxide semiconductor pattern and spaced apart from each other, of the switching transistor.

7. The method of claim 6, wherein the second photosensitive pattern comprises:
a first opening portion which is defined therein, in a first channel area defined between the first source electrode and the first drain electrode, and exposes the metal layer; and
a first half-tone portion in a second channel area defined between the second source electrode and the second drain electrode.

8. The method of claim 7, wherein the third photosensitive pattern comprises a second opening portion which is defined therein, in the second channel area, and exposes the metal layer.

9. The method of claim 8, wherein the forming the optical response pattern comprises dry etching the optical response layer.

10. The method of claim 6, wherein the first etching and the second etching comprises wet etching the oxide semiconductor layer and the metal layer, and wet etching the metal layer, respectively.

11. The method of claim 6, further comprising forming a first ohmic contact pattern and a second ohmic pattern of the sensing transistor, on the optical response pattern.

12. The method of claim 11, wherein the forming the first and second ohmic contact patterns comprises:
forming the optical response layer and an ohmic contact layer on the gate insulating layer;
forming a fourth photosensitive pattern comprising a second half-tone portion on the ohmic contact layer to correspond to a first channel area defined between the first source electrode and the first drain electrode;
first etching the optical response layer and the ohmic contact layer using the fourth photosensitive pattern as a mask to form the optical response pattern and an ohmic contact pattern;
etching back the fourth photosensitive pattern to form a fifth photosensitive pattern; and
etching the ohmic contact pattern corresponding to the first channel area using the fifth photosensitive pattern as a mask to form the first ohmic contact pattern and the second ohmic contact pattern on the optical response pattern.

13. The method of claim 12, wherein the fifth photosensitive pattern comprises a third opening portion which is defined in the first channel area and exposes a portion of the optical response pattern.

14. The method of claim 11, wherein the forming the optical response pattern comprises:
forming the optical response layer and an ohmic contact layer on the gate insulating layer;
forming the first photosensitive pattern on the ohmic contact layer; and
etching the optical response layer and the ohmic contact layer using the first photosensitive pattern as a mask to form the optical response pattern and an ohmic contact pattern.

15. The method of claim 14, wherein the forming the first and second ohmic contact patterns comprises:
forming the first, second and third oxide semiconductor patterns; and
removing a portion of the ohmic contact pattern in a first channel area defined between the first source electrode and the first drain electrode and exposed by the first and second oxide semiconductor patterns, to form the first and second ohmic contact patterns.

16. The method of claim 15, wherein the removing the portion of the ohmic contact pattern comprises dry etching the portion of the ohmic contact pattern exposed by the first and second oxide semiconductor patterns.

17. A display apparatus comprising:
a pixel substrate comprising a plurality of pixels which is disposed thereon and displays an image; and
a sensor substrate facing and coupled to the pixel substrate, and comprising:
a base substrate;
a plurality of sensing transistors which is disposed on the base substrate and senses a light;
a sensing transistor among the plurality of sensing transistors, on the base substrate and comprising:
a first gate electrode;
an optical response pattern on the first gate electrode;
a first source electrode and a first drain electrode, which are on the optical response pattern and spaced apart from each other;
a first oxide semiconductor pattern between the first source electrode and the optical response pattern; and
a second oxide semiconductor pattern between the first drain electrode and the second oxide semiconductor pattern, and
a switching transistor on the base substrate, comprising:
a second gate electrode;
a third oxide semiconductor pattern on the second gate electrode; and
a second source electrode and a second drain electrode, which are on the third oxide semiconductor pattern and spaced apart from each other.

18. The display apparatus of claim 17, wherein
the first oxide semiconductor pattern faces upper and side surfaces of a first end portion of the optical response pattern, and
the second oxide semiconductor pattern faces upper and side surfaces of a second end portion of the optical response pattern opposite to the first end portion.

19. The display apparatus of claim 18, wherein
the first source electrode exposes a portion of an upper surface of the first oxide semiconductor pattern, and
the first drain electrode exposes a portion of an upper surface of the second oxide semiconductor pattern.

20. The display apparatus of claim 17, wherein the sensing transistor further comprises a band-pass filter pattern which is between the optical response pattern and the base substrate, and filters a visible light.
